(19) United States
(12) Patent Application Publication
(10) Pub. No.: US 2021/0119039 A1
(43) Pub. Date: Apr. 22, 2021

(54) POWER SEMICONDUCTOR DEVICE AND METHOD FOR MANUFACTURING POWER SEMICONDUCTOR DEVICE

(71) Applicant: EASTWIND, LLC, Kobe-shi (JP)

(72) Inventors: Takashi Miida, Kobe-shi (JP); Ikuo Kurachi, Tokyo (JP)

(73) Assignee: EASTWIND, LLC., Kobe-shi (JP)

(21) Appl. No.: 17/119,123

(22) Filed: Dec. 11, 2020

Related U.S. Application Data
(63) Continuation of application No. PCT/JP2019/005376, filed on Feb. 14, 2019.

(30) Foreign Application Priority Data
Jun. 14, 2018 (JP) 2018-113277
Aug. 17, 2018 (JP) 2018-153351
Nov. 14, 2018 (JP) 2018-213516

(51) Int. Cl. H01L 29/78; H01L 29/16; H01L 29/66; H01L 29/04

(52) U.S. Cl. CPC H01L 29/7813; H01L 29/045; H01L 29/66734; H01L 29/1608

(57) ABSTRACT

A power semiconductor device is provided, in which a high breakdown voltage and a large current are possible, and a low on-voltage, a low switching loss, and low noise are realized. A second conductivity type block layer is provided on at least one of a first conductivity type SiC substrate, on which a SiC drift layer is formed, and a second conductivity type Si substrate, a trench gate is then provided, by bonding the SiC substrate and the Si substrate, to reach at least a part of the SiC drift layer from the Si substrate side, and a Si-MOSFET having high channel mobility and the SiC drift layer having high bulk mobility and a high breakdown voltage are combined.

### CROSS-REFERENCE TO RELATED APPLICATION

This application is a continuation application of International Application Number PCT/JP2019/005376 filed on Feb. 14, 2019, now pending, herein incorporated by reference. Further, this application is based upon and claims the benefit of priority from the prior Japanese Patent Application No. 2018-113277, filed on Jun. 14, 2018, the prior Japanese Patent Application No. 2018-213516, filed on Nov. 14, 2018 and the prior Japanese Patent Application No. 2018-153351, filed on Aug. 17, 2018, entire contents of which are incorporated herein by reference.

### FIELD

The present invention relates to a power semiconductor device suitable for a power switching element or the like and a method for manufacturing the power semiconductor device.

### BACKGROUND

In the field of power semiconductor devices, conventionally power switches such as insulated gate bipolar transistors (IGBTs) and metal oxide semiconductor field-effect transistors (MOSFETs) using Si have been widely used, but it is said that their performance is approaching its limit and becoming insufficient to clear an energy efficiency target toward a carbon-free society. On the other hand, in recent years, development of alternative techniques using new crystal materials, which are called wide band gaps, is expected, but there are many technical problems in terms of performance, cost, and, reliability, and therefore mass production is not easy, and improvement thereof is strongly desired.

### CITATION LIST

### Patent Literature

Patent Literature 1: U.S. Pat. No. 5,506,421

Patent Literature 2: U.S. Pat. No. 5,396,085

Patent Literature 3: U.S. Pat. No. 5,323,040

Patent Literature 4: U.S. Pat. No. 5,614,749

Patent Literature 5: U.S. Pat. No. 5,610,492

Patent Literature 6: Japanese Patent Application Laid-open No. 2013-243333

Patent Literature 7: Japanese Patent Application Laid-open No. 2015-153893

### Non-patent Literature

Non-Patent Literature 1: “Lateral n-channel inversion mode 4H—SiC MOSFETs,” S. Sridenvan et al. IEEE Electron Device Letters, (Volume: 19, Issue: 7, Jul. 1998)

Non-Patent Literature 2: Determination of intrinsic phonon-limited mobility and carrier transport property extraction of 4H—SiC MOSFET, Noguchi, et al. 9.3.1 IEDM17, pp 219-222. (2017)

Non-Patent Literature 3: “1800V Bipolar mode MOSFETs: a first application of Silicon wafer Direct Bonding (SDB) technique to a power device,” A. Nakagawa, IEDM86, 5.6, pp 122-125

Non-Patent Literature 4: “Bonding of Dissimilar Semiconductor Materials for Energy-Harvesting and Energy-Saving Devices,” Naoteru Shigekawa, J. Vac. Soc. Jpn. Vol. 60, No. 11, (2017) 421-427

Non-Patent Literature 5: “Impact Ionization In Silicon: A REVIEW AND UPDATE,” W. MAES, et al. Solid State Electronics Vol. 33, No. 6 pp 705-718, 1990

Non-Patent Literature 6: “Effects of thermal annealing process on the electrical properties of p+-Si/n-SiC heterojunctions,” J. Liang, S. Nishida, M. Arai, and N. Shigekawa, Applied Physics Letters 104, 161604 (2014)

### SUMMARY

Transistors that have been mainstream as power transistors are IGBTs and MOSFETs made of silicon materials (hereinafter referred to as Si). Since the IGBTs are bipolar devices, resistance of a low concentration n-type drift layer on a p-type collector layer can be reduced due to a conductivity modulation effect of carriers, and thus a high breakdown voltage and a large current can be realized. However, during a turn-off operation, high-level injected electrons and holes require carrier disappearance time due to recombination, and since it takes time to fall down, the switching operation becomes slow, and thus the turn-off loss increases. On the other hand, since MOSFETs made of Si (hereinafter referred to as Si-MOSFETs) are unipolar devices, the recombination speed does not cause a problem in a low concentration drain diffusion layer (hereinafter referred to as a drift layer) on a high concentration drain diffusion layer, and thus the advantage of reducing turn-off loss is elicited. However, in a case in which the drift layer is thickened to increase a breakdown voltage for high-voltage applications, on-resistance thereof will increase, and there is a drawback that an on-voltage rises and an energy loss increases, which makes it unsuitable for high-voltage applications. FIG. 3A shows a cross-sectional view of a Si-MOSFET of a conventional example.

Due to technical limitations of Si devices as described above, wide bandgap semiconductors have been expected as a replaceable next-generation power semiconductor material in recent years. Among them, silicon carbide (hereinafter referred to as SiC) and gallium nitride (hereinafter referred to as GaN) both have a band gap of about 3 times that of Si, and also have a dielectric breakdown voltage of about 10 times that of Si, while their mobility is equivalent to that of Si. Due to such advantages, wafers can be thinned and used even for use in high voltage applications, on-resistance can be lowered, and thus high voltage and high speed operations are possible. Further, high temperature operations are possible, cooling becomes easier since high thermal conductivity and excellent heat dissipation are achieved, and thus they are highly anticipated as power semiconductor device materials for high-speed and high-power uses. However, there are problems in manufacturing that SiC has a high wafer cost and requires heat treatment at a high temperature in a wafer process as compared with Si.

Although a long period of time has passed since research on MOSFETs made of SiC crystals (hereinafter referred to as conventional SiC-MOSFETs) started (see, for example, Non-Patent Literature 1), a cause of the problem of low channel mobility of conduction electrons (about two orders of magnitude smaller than Si) due to quality of an interface of a gate thermal oxide film has not yet been fully identified. The cause is presumed to be that channel mobility decreases because there are many defects (interface state density) at an interface between a gate insulating film and SiC (see, for example, Non-Patent Literature 2). That is, it is known that although electron mobility in bulk crystals of SiC is 800-1000 cm/V·sec, surface channel mobility in SiC-MOSFETs is extremely low at 10 cm/V·sec (Si surface).

For that reason, although resistance of a SiC drift layer formed on a substrate drain diffusion layer is sufficiently low during a device operation, channel resistance of a MOSFET is too high, which is a serious problem. As a result, on-voltage rises and energy loss increases, and thus advantages of SiC cannot be fully utilized. FIG. 3B is a cross-sectional view of a SiC-MOSFET of a conventional example. Here, an interface state 71 below a gate oxide film hinders channel electron conduction, and thus current gain decreases. Further, in a trench type vertical SiC-MOSFET structure (see, for example, Patent Literature 1), even if a gate oxide film is thinned to increase driving ability, quality of a SiC thermal oxide film easily deteriorates and a breakdown voltage is low, and thus failure due to dielectric breakdown occurs frequently at a bottom corner 73 of a gate. Although various annealing methods have been tried as means for improving a state of a SiC interface and quality of a thermal oxide film quality having many defects, a root cause of deterioration has not been fully explained. For that reason, a drastic review from basic principles is required for understanding the interface state (see, for example, Non-Patent Literature 2). In such a situation, a problem to be solved by the present invention is to realize a MOSFET using SiC crystal by which on-operation loss is small and a high breakdown voltage can be achieved.

In order to solve the problem in the conventional examples, Patent Literature 2 has devised a structure in which a Si-MOSFET is stacked on SiC. FIG. 8 shows a cross-sectional view of the known example. In this structure, sidewall gates 50 are used for a mesa type Si-MOSFET, and thus a MESFET having SiC Schottky junction gates 62 provided at a bottom of a trench thereof is used as an active load. This structure is considered to be based on the intention that channel resistance is lowered by the Si-MOSFET and on-resistance of the entire device is lowered by using a SiC substrate 48 having a low resistance in a drift layer. Since a permissible electric field intensity (0.33 MV/cm) in Si is only about 1/10 that of SiC, avalanche breakdown will occur unless it is attenuated by more than one order of magnitude from a high electric field (>1 MV/cm) in SiC, but since an N⁺ layer 57 is formed on a bottom side of the mesa-type Si, a Si potential is conversely increased by a strong electric field from the SiC drift layer in an off state. However, the patent explains that penetration of an electric field into Si can be inhibited due to a potential drop resulting from a narrow channel effect provided by making a mesa width (a channel width) as narrow as possible in order to attenuate the electric field, but since a large potential rise occurs due to high-density n-type space charges, it goes against relaxation and no effect can be expected.

On the other hand, in the patent, lower ends of the side wall type trench gates 50 in FIG. 8 are located above heterojunction positions 56′ between Si and SiC in an on state, and thus, under a surface potential of a SiC region, the electrons influenced by an electric field effect from the trench gates cannot overcome a conduction band step and hinder channel conduction. However, in the structure of the patent, Schottky electrodes 52 must be formed on bottom and side surfaces of the trench to form MESFETs, and since it is necessary to bring upper ends of the electrodes as close as possible to the SiC/Si interface, it is impossible to physically lower positions of the lower ends of the sidewall gates from the heterojunction positions. Further, Patent Literature 7 proposes bonding an n-type SiC substrate provided with a drift layer and a p-type Si substrate using a surface activation bonding method and then providing trench gate electrodes that reach the SiC drift layer. That is, it is a combination of the Si-MOSFET section shown in FIG. 3A and the SiC drift layer shown in FIG. 3 B. However, there are concerns, for example, if an impurity concentration of the p-type Si substrate is low, it is not possible to block intrusion of an electric field from the SiC side, and a punch-through phenomenon in which a depletion layer reaches a source, and electrons accelerated by an electric field cause impact ionization in Si, causing avalanche breakdown. On the other hand, if the impurity concentration of the p-type Si substrate is increased, the entire p-type Si substrate (p-type Si layer) becomes an effective channel length, and thus, if a thickness of the Si substrate varies, there is a problem that a stable current may not flow.

In the present invention, by stacking a drift layer made of SiC with high bulk mobility on a Si-MOSFET with high channel mobility, a new device structure that can achieve high performance and its manufacturing method are devised, thereby solving the problems of the above existing devices. Specific means for solving the problems will be exemplified below.

In a power semiconductor device according to the present invention, a first conductivity type SiC substrate that has a drain electrode, a first conductivity type drain layer, and a first conductivity type drift layer in order from a bottom surface side thereof, and a second conductivity type Si substrate thereon, which is the opposite conductivity type of the first conductivity type, are directly bonded together. Grooves (recess grooves) extending from a Si surface side through the Si substrate to a part of the SiC substrate are provided, and polycrystalline Si is embedded therein through respective gate oxide films, thereby forming trench gates. Here, bottom surface positions of the trench gates are lower than a bonding position between the SiC and the Si. On the other hand, it is characterized in that a second conductivity type impurity region (hereinafter referred to as a block layer) having a higher concentration than the Si substrate is formed in the vicinity of a bottom side between the trench gates in a horizontal direction in the second conductivity type Si substrate, and a gate electrode wiring and a source electrode wiring are provided on an upper portion on a front surface side of the second conductivity type Si substrate, whereby a MOSFET is manufactured.

Lower end positions of the trench gates are at or deeper than a heterojunction position between the drift layer of the first conductivity type SiC and the second conductivity type Si substrate, and are, for example, 0.2 μm or deeper, preferably 0.5 μm to 0.7 μm. If it is 0.7 μm or more, a feedback capacitance Cᵣₛₛ, which is a parasitic capacitance between a gate electrode and a drain electrode, increases, which is not desirable. By setting the above lower end positions, an electric field effect is exerted on a MOS interface of the SiC drift layer in an on state, so that conduction electrons can easily overcome an energy step of a Si/SiC conduction band heterojunction to smoothly flow a drain current. On the other hand, in an off state, a reverse bias state occurs, and thus a high electric field from the first conductivity type SiC drift layer must be attenuated in the second conductivity type Si substrate, but by disposing the SiC drift layer and the Si substrate interface in an inward direction between the trench gates, they become walls of the electric field, so that intrusion of the electric field into Si can be relaxed. Further, if corners of bottom portions of the trench gates are sharp, dielectric breakdown may occur due to electric field concentration, and thus it is necessary to round the corners. For example, radii of curvature thereof may be 0.05 μm or more. This is because the electric field strength is inversely proportional to the radius of curvature of the gate, and it is desirable that the curvature be half the width of the gate if possible.

In the power semiconductor device according to the present invention, the electric field on the second conductivity type Si substrate must be significantly more relaxed in the off state. Preferably, it is effective to set the interval to be narrower such that a potential distribution in Si is spatially modulated and lowered due to a narrow channel effect generated between the trench gates to weaken the electric field strength. In addition to that, a measure by which the intrusion of the electric field into Si can be further prevented by providing a second conductivity type block region at a bottom portion of the second conductivity type Si substrate has been devised. By providing the block layer, a depletion layer width can be limited to the off state, and thus it is not necessary to rely on excessively narrowing only the interval between the trench gates. Further, since the block layer determines a channel surface potential and determines a substantial channel length even in the on state, resistance to avalanche breakdown associated with impact ionization increases as compared to Patent Literature 7 mentioned above, and it is possible to supply a stable current regardless of a thickness of the Si substrate. As described above, in the present invention, it is possible to stably achieve high performance in the on state and the off state by introducing the SiC recess grooves of the trenches, the narrow channel effect between the gates, and the block layer formation.

In a method for manufacturing a power semiconductor device according to the present invention, a SiC wafer on which a first conductivity type drift layer is formed and a second conductivity type Si wafer are integrated using a surface activated bonding technique (see, for example, Non-Patent Literature 3 and 4), which is then polished and formed into thin film, and then trench grooves are dug from a Si side to penetrate the Si substrate and a part (recess groove) of the SiC substrate. Then, after forming respective gate oxide films therein, gate electrodes are formed by filling polycrystalline Si into the trenches. It is characterized in that a second conductivity type block layer is formed on a bottom portion of the second conductivity type Si substrate between the trench gates, and a first conductivity type diffusion layer and a second conductivity type diffusion layer for electrical bonding with a source region and the substrates, and electrodes in contact with the first conductivity type diffusion layer and the second conductivity type diffusion layer are formed.

The MOSFET with which low loss and high breakdown voltage can be achieved has been devised on the basis of the device structure and the method for manufacturing suitable for this according to the present invention. The problem that needed to be solved of deterioration of channel mobility due to defects in the interface of the SiC oxide film in the on state operation can be avoided by converting the channel to a MOS channel using Si crystals. In particular, by sufficiently overlapping the trench gates on the SiC (recess groove) side with respect to the SiC/Si heterojunction portion, electrons are caused to easily overcome the conduction band energy step in the on state, so that a large drain current can be taken out. In addition, by providing the second conductivity type block layer on the bottom portion of the second conductivity type Si substrate, the actual channel length is determined, and thus a stable current can always flow even when the thickness of the substrate varies slightly. With this structure, high conductivity can be stably maintained over the entire conductive region made of Si and SiC from the source to the drain, and thus a low on voltage can be achieved. In addition, since the Si-MOSFET structure is adopted for the input, a gate input pulse amplitude thereof can be lower than in conventional SiC-MOSFETs, and thus oscillation noise and radiation can also be reduced.

On the other hand, there is no measure other than thickening the drift layer to increase the breakdown voltage in the conventional Si-MOSFET in the off state, but particularly in the present invention, since SiC is used for the drift layer, the performance can be significantly improved. As a measure to prevent a strong electric field from the drift layer of SiC from entering the Si region, the narrow channel effect caused by narrowing the space between the trench gates, and the formation of the second conductivity type block layer formed in the Si surface region, which enhances the narrow channel effect, can effectively prevent the penetration of the electric field into Si. Further, forming the trench gates up to the SiC region (recess grooves) is also effective in inhibiting the electric field from entering the second conductivity type Si substrate. By properly combining these measures, it is possible to realize low on-resistance and inhibit avalanche breakdown in the Si substrate in a high voltage off state and thus high device performance that could not be achieved with conventional Si-MOSFETs, Si-IGBTs, and SiC-MOSFETs is achieved.

### BRIEF DESCRIPTION OF DRAWINGS

FIG. 1 is a cross-sectional structural view of a device according to the present invention.

FIGS. 2A and 2B are energy band diagrams of the present invention, in which FIG. 2A shows an on operating state and FIG. 2B shows an off operating state.

FIGS. 3A and 3B are explanatory views of a conventional example, in which FIG. 3A is a cross-sectional view of a Si-MOSFET of a conventional example and FIG. 3B is a cross-sectional view of a SiC-MOSFET of a conventional example.

FIG. 4A to 4C are schematic diagrams of a modulation effect of a potential distribution due to a difference in channel width between FIG. 4A and FIG. 4B and presence/absence of p-type block layer formation of FIG. 4B and FIG. 4C in the present invention.

FIGS. 5A and 5B show simulation results of the device for an electric field distribution at the center position between gates due to the narrow channel effect that occurs between gates and an electric field distribution with or without a p-type block diffusion layer on a Si surface layer at a center position between gates in the present invention.

FIGS. 6A and 6B are diagrams illustrating the steps of manufacture of the present invention.

FIGS. 6C and 6D are diagrams illustrating the steps of manufacture of the present invention after the step in FIG. 6B.

FIG. 6E and 6F are diagrams illustrating the steps of manufacture of the present invention after the step in FIG. 6D.

FIG. 6G and 6H are diagrams illustrating the steps of manufacture of the present invention after the step in FIG. 6F.

FIG. 7 is a cross-sectional view of a power semiconductor device according to a second embodiment of the present invention.

FIG. 8 is a cross-sectional view of a known example of a device in Patent Literature 1.

### DESCRIPTION OF EMBODIMENTS

The present invention proposes a new power MOSFET structure in which a MOSFET portion is made of Si and a drift layer portion is made of SiC, and proposes, as a manufacturing method thereof, a manufacturing process in which a Si substrate and a SiC substrate can be integrated using a method of direct bonding.

### First Embodiment

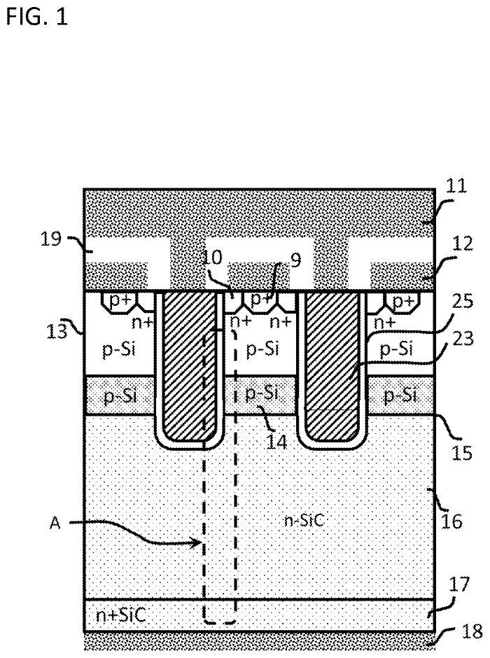

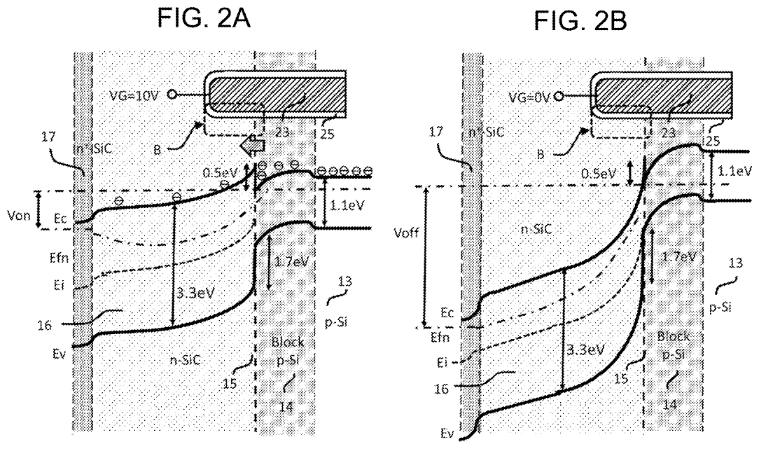

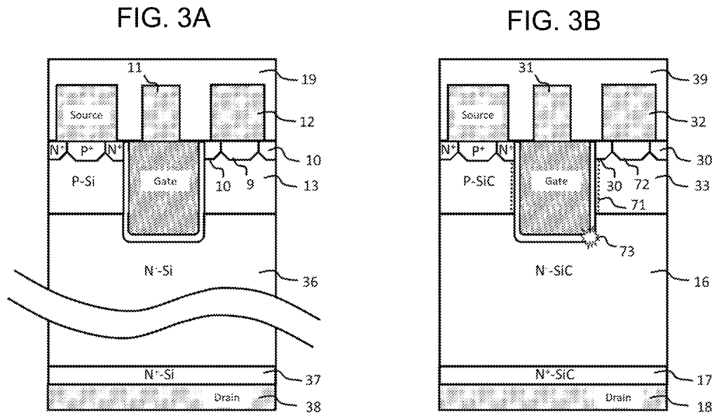

A first embodiment will be described in detail below with reference to FIGS. 1, 2A and 2B. FIG. 1 is a cross-sectional structural diagram of a MOSFET according to the first embodiment of the present invention. Reference numeral 9 in the figure is a second conductivity type, for example, a p-type diffusion layer, and reference numeral 10 is a first conductivity type, for example, an n⁺-type source diffusion layer. Hereinafter, the first conductivity type is referred to as an n-type, and the second conductivity type is referred to as a p-type, but the reverse is also possible. Reference numeral 11 is a gate electrode, reference numeral 12 is a source electrode, reference numeral 13 is a p-type Si bulk layer, and reference numeral 14 is a p-type block region having a higher impurity concentration than the p-type Si bulk layer. In addition, an impurity concentration of the p-type Si bulk layer 13 is set to be 1.0×10¹⁶ cm⁻³ to 1.0×10¹⁷ cm⁻³, an impurity concentration of the p-type block layer 14 is preferably set to be 1.0×10¹⁷ cm⁻³ or more, and here, the impurity concentration of the p-type Si bulk layer 13 is set to be 5.0×10¹⁶ cm⁻³, and the impurity concentration of the p-type block layer 14 is set to be 1.0×10¹⁷ cm⁻³. Reference numeral 16 is an n⁻-type SiC drift layer, reference numeral 17 is an n-type SiC drain layer, reference numeral 18 is a drain electrode, and reference numeral 19 is a passivation film. Unlike conventional SiC-MOSFETs, the p-type block layer 14, the n⁺-type source diffusion layer 10, the p-type substrate contact diffusion layer 9, and the p-type bulk layer 13 in a MOSFET region are formed in the Si substrate, and the n⁺-type SiC drain layer 17 and the n⁻-type SiC drift layer 16 are formed in the SiC substrate. As shown in the figure, depths of trench gate electrodes 23 in a trench direction are equal to or deeper than that of a Si/SiC heterojunction interface 15. Here, the depths are 0.6 μm. Also, the trench gate electrodes 23 are made of polycrystalline Si or a metal, but here, the trench gate electrodes 23 are made of polycrystalline Si. The p-type block layer 14 in the p-type Si bulk layer 13 is formed in the vicinity of the Si/SiC heterojunction interface 15 between the n⁻-type SiC drift layer 16 and the p-type Si bulk layer 13. Here, consideration is given such that, by overlapping bottoms of the gate electrodes 23 with the heterojunction, a gate electric field and a channel current path are not blocked in a drift region. Further, in the first embodiment, using a manufacturing method which will be described later, the n⁺-type source region 10 and the p-type Si bulk layer 13 that forms a channel region under the gate extraction electrode 11 in a portion corresponding to the MOSFET portion are formed in the Si substrate, the other n⁻-type SiC drift layer 16 and n⁺-type SiC drain layer 17 are formed in the SiC substrate, and the p-type Si substrate and the n⁻-type SiC drift layer 16 are directly bonded to face each other.

Regarding the junction thus manufactured, an operation of the MOSFET of the first embodiment will be described from the viewpoint of energy band. FIG. 2A is an on-state energy band diagram in a broken line portion A shown in FIG. 1 and illustrates a mechanism for injecting electrons into the drift layer at the Si/SiC heterojunction interface 15 in an on state. As shown here, since an energy state of SiC at a conduction band end is 0.5 eV higher than that of Si in the energy band diagram in the on state, it becomes a barrier for conduction electrons, and free electrons in Si are filled up to the energy conduction band end of SiC due to a gate electric field in the MOS structure. In order for the conduction electrons to overcome this energy barrier, when an electric field is applied from the trench gate electrode 23 in the MOS structure in the SiC (recess groove) to increase a SiC surface potential, the electrons easily overcome the energy barrier of the SiC, and the electrons can be injected into the n⁻-type SiC drift layer 16. On the other hand, since a channel potential is low in the p-type block layer 14, a current is controlled by the electric field effect in this region, and thus it can be regarded as a substantial channel length. In this way, a drain current always becomes stable regardless of a thickness of the p-type Si bulk layer 13.

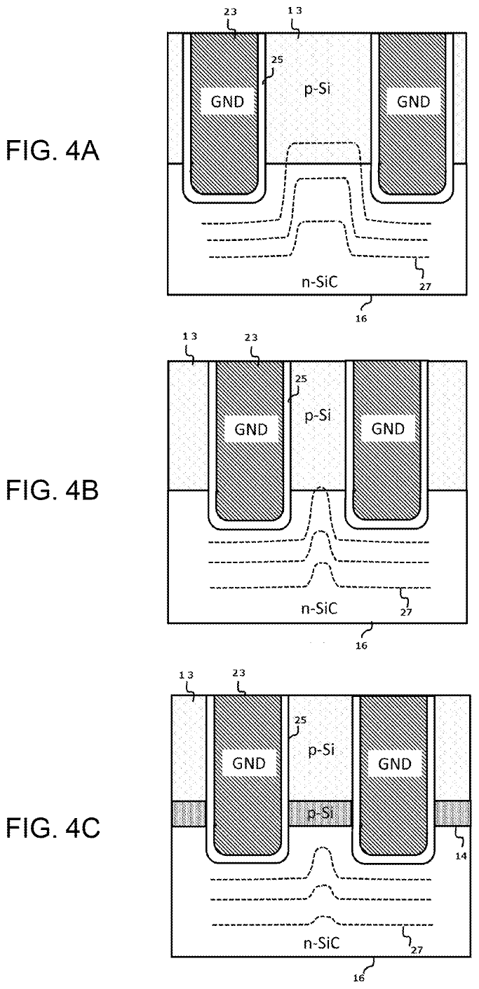

On the other hand, FIG. 2B shows an energy band diagram in the off state. Since it is in a reverse bias state here, there is a concern that, in a case in which the electric field enters the p-type Si bulk layer 13 from the n⁻-type SiC drift layer 16 and an electric field strength exceeding a permissible level (0.33 MV/cm) in Si is generated, impact ionization will occur in Si, which would cause avalanche breakdown. A first measure against this is a narrow channel effect in the p-type Si bulk layer 13. This can inhibit penetration of the electric field into the p-type Si bulk layer 13 by narrowing a width of the p-type Si bulk layer 13 between the two gates and modulating a potential distribution using a spatial edge effect of gate electrode ends at the ground potential. In order to further inhibit the electric field, it is necessary to narrow the width of the p-type Si bulk layer 13 to a limit of semiconductor miniaturization. FIG. 4A shows a schematic diagram in which the potential distribution is spatially modulated due to a difference in channel width when the channel width is wider and FIG. 4B shows the case in which it is narrower.

On the other hand, as a second measure, by forming the p-type block layer 14 having a higher impurity concentration than the p-type Si bulk layer 13 in a bottom region of the p-type Si bulk layer 13 with respect to the penetration of the electric field from the n⁻-type SiC drift layer 16, it is possible to effectively prevent the penetration of the electric field into the p-type Si bulk layer 13. A difference between presence and absence of the p-type block layer 14 is shown in FIG. 4B and 4C. Also, here, the impurity concentration of the p-type Si bulk layer 13 is set to be 5.0×10¹⁶ cm⁻³, and the impurity concentration of the p-type block layer 14 is set to be 1.0×10¹⁷ cm⁻³.

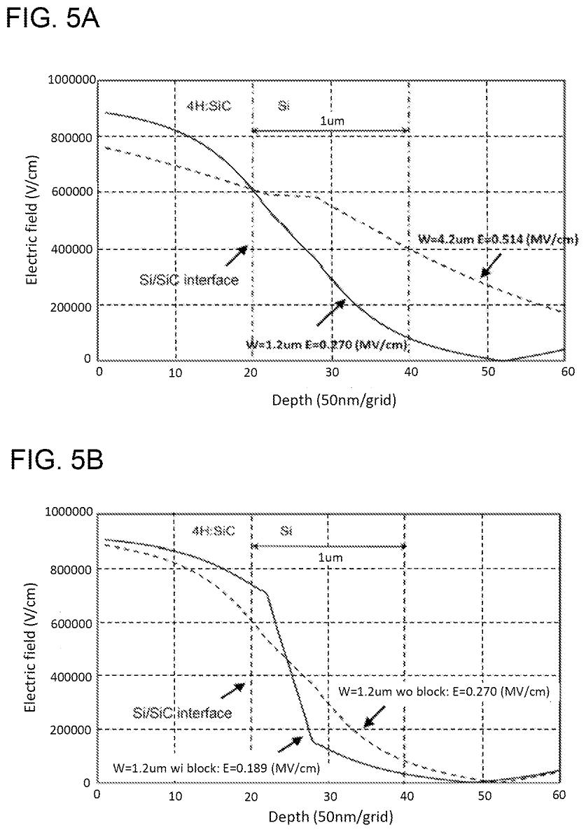

In order to predict effects of these two electric field relaxation methods, an electric field distribution in a depth direction in the off state is shown in FIG. 5A and 5B. Here, 0 V was applied to the trench gate electrodes 23, 1,000 V was applied to the drain electrode 18, and a thickness of the n⁻-type SiC drift layer 16 was set to be 10 μm. FIG. 5A shows a change in average electric field per 1 μm in Si in the vicinity of the Si/SiC heterojunction interface 15 in a case in which an interval W between the trench gate electrodes 23 is narrowed from 4.2 1 μm (a broken line) to 1.2 μm (a solid line) in order to investigate the narrow channel effect, which is the first measure, in the first embodiment. Here, it can be seen that the electric field is significantly reduced in a narrow channel (W=1.2 μm). This simply demonstrates that the electric field from the n⁻-type SiC drift layer 16 is modulated by a spatial edge effect to reduce the potential. Further, FIG. 5B shows results regarding presence/absence of the p-type block region 14 on the Si surface, which is the second measure. It is clear that the electric field strength is further reduced when the block layer is present (a solid line). Also, from the tendency extrapolation comparing W=4.2 μm and W=1.2 μm shown in FIG. 5A and 5B, the effect can be expected when the interval W is 2.0 μm or less.

In addition, providing the overlapping region (recess grooves) between the trench gate electrode 23 and the n⁻-type SiC drift layer 16 shown in B of FIG. 2A and 2B is also effective in preventing penetration of an excessive electric field into Si in the off state. This is because the trench gate electrode 23 act as a barrier and the electric field does not easily reach the heterojunction. As described above, it is clear from electric field dependence of an ionization constant of Non-Patent Literature 7 that the electric field entering Si has an average value of less than 0.2 MV/cm for a depth of 1 μm due to the combination of the narrow channel effect between the gates, the effect of the p-type block layer, and the gate overlapping effect on the heterojunction, and the ionization multiplying coefficient is about 0.1 and has sufficiently reduced to a level at which avalanche breakdown does not occur.

Next, a method of manufacturing the MOSFET shown in the first embodiment, in which the element structure is formed after the SiC wafer and the Si wafer are directly bonded and integrated, will be described.

Direct wafer bonding has preferably been used for manufacturing power semiconductors (see, for example, Non-Patent Literature 3), and as a method of directly bonding such different semiconductor wafers, a solid bonding method performed by a surface activated bonding technique (hereinafter referred to as SAB) that maintains integrity of crystals by irradiating a surface with neutral atomic beam, removing a natural oxide film, making a surface layer in an amorphous state, and pressing it has been realized, and thus heterojunction devices are realized (see, for example, Non-Patent Literature 4). In addition, an amorphized portion is recrystallized by post-annealing after pressurization to obtain a continuous crystal interface. Non-Patent Literature 5 shows a bonding example of n⁺-type Si/n-type SiC (4H crystal structure) and diode characteristics improved by annealing. Further, an interface state present on a wafer bonding surface is significantly improved by annealing treatment after SAB bonding.

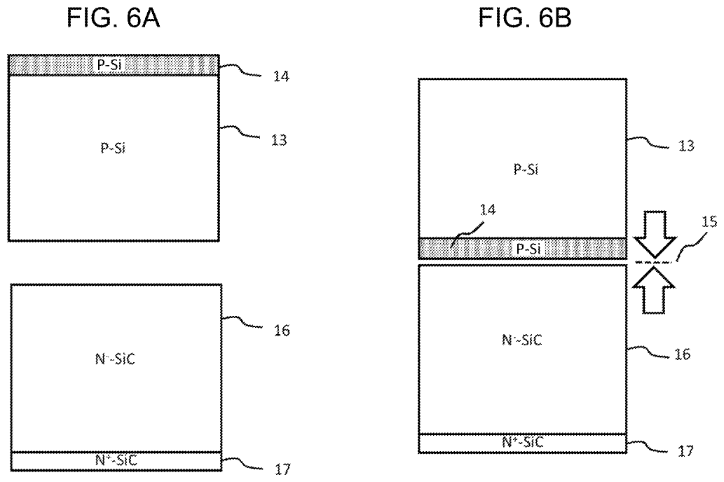

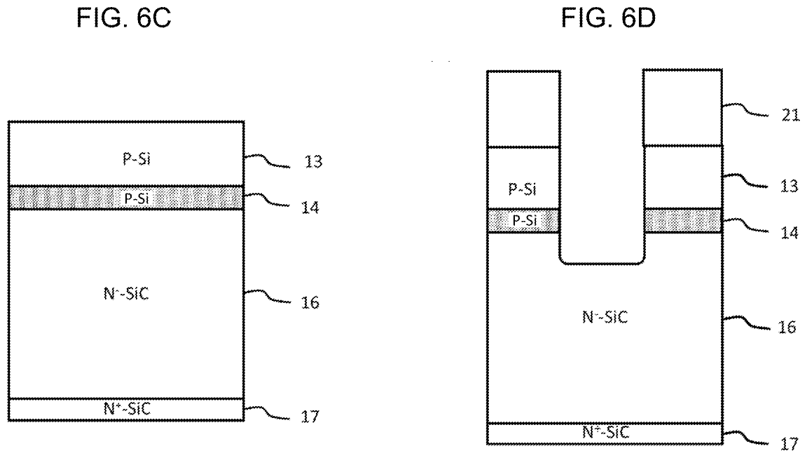

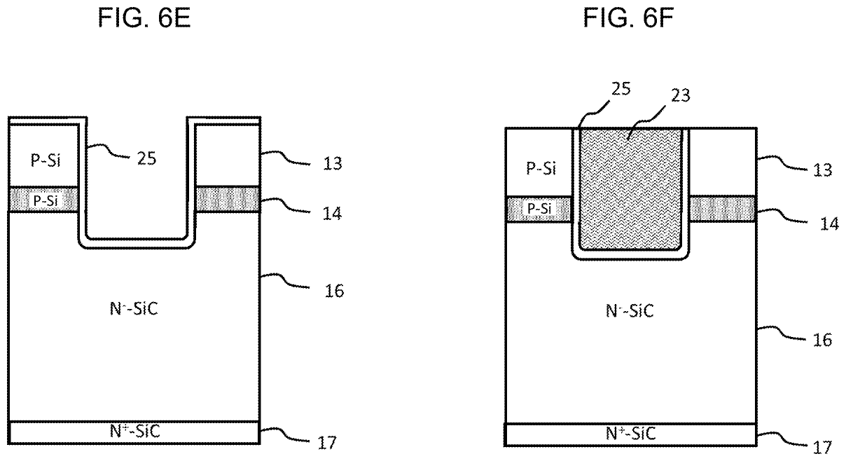

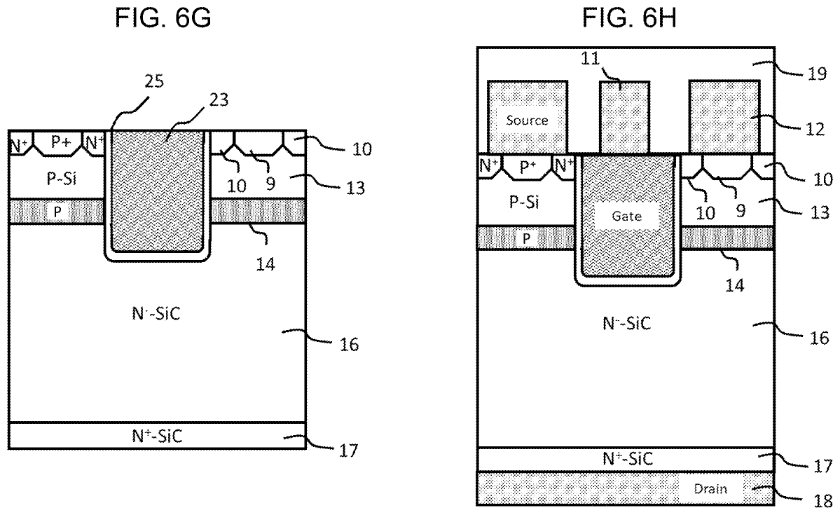

An example of the manufacturing method according to the first embodiment will be described in detail below with reference to FIGS. 6A to 6H, in which there may be one recess gate, but in reality, there are a plurality of recess gates in order to increase the channel width, and usually two recess gates are provided in parallel. Here, only one recess gate is shown for the sake of simplicity. In the step of FIG. 6A, the p-type block layer 14 is formed by ion implantation of boron on a surface of the p-type Si wafer (p-type Si bulk layer) 13. On the other hand, in the SiC wafer having a Si plane as a main surface in a 4H crystal structure, the n⁻-type SiC drift layer 16 is grown using epitaxial growth on the n⁺-type SiC wafer substrate 17 serving as the drain layer. Next, in the step of FIG. 6B, surfaces of the p-type Si wafer 13 and the n⁻-type SiC drift layer 16 are irradiated with neutral atomic beams such as ions and Ar to remove natural oxide films and activate the surfaces, and then are integrated using the SAB method. In addition, here, although the impurity concentration of the n⁺-type SiC wafer substrate (n⁺-type SiC drain layer) 17 is arbitrary, it is set to be 1.0×10²⁰ cm⁻³ here, and although the impurity concentration of the n⁻-type SiC drift layer 16 is also arbitrary, it is set to be 6.0×10¹⁵ cm⁻³ here. Further, in order to decrease a lattice mismatch between the SiC wafer having the Si plane as the main surface and the p-type Si wafer 13 in the 4H crystal structure to reduce the interface state, it is preferable that the main surface of the p-type Si wafer 13 be the (111) plane.

Next, in the step of FIG. 6C, a back surface of the p-type Si wafer 13 is polished and flattened to a thickness of about 1 μm using a chemical mechanical polishing (CMP) method. Next, a hard mask 21 is formed in the step of 6D, and parts of the p-type Si wafer 13 and the n⁻-type SiC drift layer 16 are etched using reactive ion etching (RIE) or the like. An etching depth (recess groove) of the n⁻-type SiC drift layer 16 is preferably about 0.5 μm or 0.6 μm. Also, corners of the trench are rounded to a radius of curvature of half the maximum gate width, for example, 0.05 μm or more is preferable from the viewpoint of electric field relaxation in the oxide film. In addition, the hard mask 21 is formed of, for example, a SiO₂ film. Next, the gate oxide film 25 is formed in the step of FIG. 6E, polycrystalline Si is grown in the trench in the step of 6F, and the surface of the p-type Si wafer 13 is polished and flattened using CMP. Here, the gate oxide film 25 is formed of SiO₂. Next, in the step of FIG. 6G, large current ions of phosphorus are implanted to form the n⁺-type source region 10, and large current ions of boron are implanted to form the p⁺-type substrate contact layer 9. Finally, in the step of 6H, the source electrode 12 and the gate extraction electrode 11 that also serve as substrate contact electrodes are formed, and the coating insulating film 19 is formed. Further, in reality, as shown in FIG. 1, the source electrode 12 is formed and then the coating insulating film 19 is formed, and a contact hole is formed in the coating insulating film 19 to reach the trench gate electrode 23 and then the gate extraction electrode 11 is formed.

### Second Embodiment

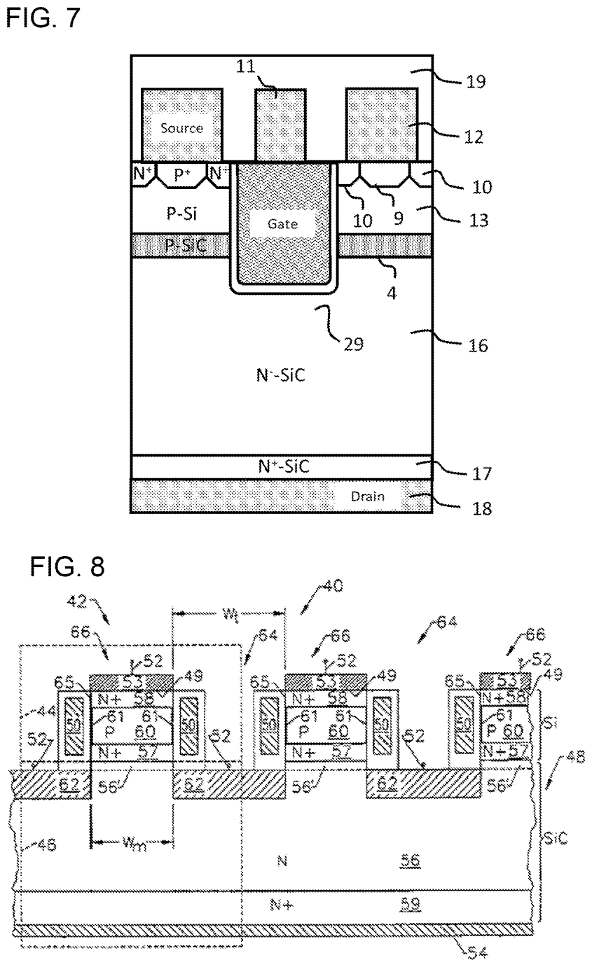

Next, a second embodiment of the present invention will be described with reference to FIG. 7. In the second embodiment, a p-type SiC block layer 4 is formed on the n⁻-type SiC drift layer 16, the p-type Si bulk layer 13 on which the p-type block layer 14 is not formed is directly bonded thereon, and other configurations are the same as in the first embodiment. In this case, a load in Si having a narrow bandgap is reduced by relaxing the electric field in the p-type SiC block layer 4. In the second embodiment, the p-type SiC block layer 4 becomes a substantial channel length, but since mobility of SiC is extremely low, channel resistance can be minimized by making a thickness of the p-type SiC block layer 4 as thin as possible at about 0.1 μm to 0.3 μm. Further, a concentration thereof is preferably 1.0×10¹⁶ cm⁻³ to 1.0×10¹⁷ cm⁻³ from the viewpoint of threshold values. When the electric field can be relaxed by the p-type SiC block layer 4, the avalanche breakdown and the electrons captured at the interface state between Si and SiC can reduce a leakage current due to inter-band tunnel. In addition, in each of the above embodiments, SiC having a 4H crystal structure with an E_{g} of 3.3 eV is used as a wide-gap semiconductor. However, the wide-gap semiconductor is not limited to SiC, and GaN (E_{g}=3.4 eV), diamond (E_{g}=5.5 eV) or β-Ga₂O₃ (E_{g}=4.8 eV to 4.9 eV) may be used.

### INDUSTRIAL APPLICABILITY

According to the present invention, a power semiconductor having high power, high efficiency, and low noise is realized, which contributes to reduction of total power consumption in social infrastructure and also contributes to improvement of environmental problems such as global warming.

### REFERENCE SIGNS LIST

4 p-type SiC block layer

9 p⁺-type substrate contact layer

10 n⁺-type source region

11 Gate extraction electrode

12 Source electrode

13 p-type Si bulk layer

14 p-type block layer

15 Si/SiC heterojunction interface

16 n⁻-type SiC drift layer

17 n⁺-type SiC drain layer

18 Drain electrode

19 Coating insulating film

22 Trench

23 Trench gate electrode

25 Gate oxide film

27 Potential distribution contour line

29 Trench gate bottom oxide film

30 n-type source diffusion layer

31, 32 Gate electrode

33 p-type SiC region

36 n-type drift region

37 n-type drain diffusion region

38 Drain electrode

39 Insulating protective film

42 Device of known example of Patent Literature 1

48 SiC substrate

49 Sidewall gate

52 Source electrode

54 Drain electrode

56′ n-type layer SiC drift layer/n-type Si layer interface

57 n-type layer Si diffusion layer

58 n-type Si source diffusion layer

59 n-type layer SiC drain diffusion layer

60 p-type Si substrate

61 Gate oxide film

62 Schottky junction electrode

71 Interface state

72 Drain diffusion layer

73 Trench corner gate oxide film

What is claimed is:

1. A power semiconductor device comprising:
a wide-gap semiconductor substrate which has a first conductive type drain layer, and a first conductive type drift layer having a lower impurity concentration than the drain layer;
a second conductive type Si substrate which is directly bonded to the drift layer and is a reverse conductive type to the first conductive type; and
a second conductive type block layer which is between the drift layer and the Si substrate, and which blocks an electric field from entering the Si substrate, wherein
the Si substrate has a trench which reaches at least the drift layer,
the power semiconductor device further comprising:
a gate insulating film provided on at least an inner surface of the trench;
a trench gate electrode in which the gate insulating film is embedded;
a first conductive type source region and a second conductive type substrate contact region provided on an exposed surface side of the Si substrate;
a source electrode connected to the source region and the substrate contact region; and
a drain electrode connected to the drain layer, and wherein
the second conductive type block layer is in contact with the gate insulating film, and
the wide-gap semiconductor is either an SiC, a GaN, a diamond or a β-Ga₂O₃.

2. The power semiconductor device according to claim 1, wherein a bonding interface between the wide-gap semiconductor substrate and the Si substrate is a surface activated bonding interface.

3. The power semiconductor device according to claim 1, wherein a tip portion of the trench gate electrode reaches at least the drift layer.

4. The power semiconductor device according to claim 3, wherein an angle of the tip portion of the trench gate electrode is at least 0.05 μm and has a round having a radius of curvature of half a width of the trench gate electrode at a maximum.

5. The power semiconductor device according to claim 1, wherein the trench gate electrode is provided in plurality in parallel, and a width of the Si substrate sandwiched between the trench gate electrodes in a horizontal direction is 2 μm or less.

6. The power semiconductor device according to claims 1, wherein the block layer is a second conductive type Si block layer having a higher impurity concentration than the Si substrate.

7. The power semiconductor device according to claim 1, wherein the block layer is a second conductive type SiC block layer having a higher impurity concentration than the drift layer provided on a side of bonding interface with the Si substrate.

8. The power semiconductor device according to claims 1, wherein the wide-gap semiconductor substrate is a SiC substrate having as a main surface a Si plane in a 4H crystal structure, and the Si substrate is a Si substrate having as a main surface a (111) plane.

9. A method for manufacturing a power semiconductor device, the method comprising:
epitaxially growing a first conductive type drift layer on a first conductive type drain layer to form a wide-gap semiconductor substrate;
forming a second conductive type block layer on an entire surface of the drift layer or on an entire surface of a second conductive type Si substrate, which is a reverse conductive type to the first conductive type;
irradiating a surface on the drift layer side and a surface on a Si substrate side with ions or Ar neutral atom beam to remove natural oxide films and activate the surfaces;
integrating the wide-gap semiconductor substrate and the Si substrate to each other by directly bonding;
polishing the Si substrate to a thickness of 0.5 μm to 1.2 μm; and
forming on the Si substrate a trench that reaches at least the drift layer.
